(19) United States
(12) Patent Application Publication
(10) Pub. No.: US 2026/0164729 A1
(43) Pub. Date: Jun. 11, 2026

(54) GROUP III-V POWER SEMICONDUCTOR DEVICE AND METHOD OF MANUFACTURING SAME

(71) Applicant: DB HiTek Co., Ltd., Bucheon-si (KR)

(72) Inventors: Jun Hyeok LEE, Eumseong-gun (KR); Woo Chul JEON, Eumseong-gun (KR); Jong Hyun LEE, Eumseong-gun (KR); Ji Houn JUNG, Eumseong-gun (KR); Hee Sub LEE, Eumseong-gun (KR); Min Su CHO, Eumseong-gun (KR)

(21) Appl. No.: 19/079,676

(22) Filed: Mar. 14, 2025

(30) Foreign Application Priority Data
Dec. 11, 2024 (KR) 10-2024-0183577

(51) Int. Cl. H10D 62/10; H10D 30/01; H10D 30/47; H10D 62/60; H10D 62/824; H10D 64/00

(52) U.S. Cl. CPC H10D 62/102; H10D 30/015; H10D 30/4755; H10D 62/60; H10D 62/824; H10D 64/112

(57) ABSTRACT

Proposed are a group III-V power semiconductor device and a method of manufacturing the same. More particularly, proposed are a group III-V power semiconductor device in which one or more electric field relaxation regions are formed on a barrier layer, preferably between a capping layer and a drain electrode, thereby relaxing the peak electric field between a gate electrode and the drain electrode so that the characteristics of the device are improved, and a method of manufacturing the same.

### CROSS REFERENCE TO RELATED APPLICATION

The present application claims priority to Korean Patent Application No. 10-2024-0183577, filed Dec. 11, 2024, the entire contents of which is incorporated herein for all purposes by this reference.

### BACKGROUND

### Technical Field

The present disclosure relates to a group III-V power semiconductor device and a method of manufacturing the same. More particularly, the present disclosure relates to a group III-V power semiconductor device in which one or more electric field relaxation regions are formed on a barrier layer, preferably between a capping layer and a drain electrode, thereby relaxing the peak electric field between a gate electrode and the drain electrode so that the characteristics of the device are improved, and a method of manufacturing the same.

### Description of the Related Art

Nitride-based semiconductors are being applied to high-withstand voltage and high-power semiconductor devices through high electron saturation velocity and wide band gap characteristics. In particular, gallium nitride (GaN) has high breakdown field characteristics and wide band gap characteristics compared to silicon and gallium arsenide (GaAs) and thus exhibits excellent breakdown voltage characteristics when applied to transistors.

In addition, GaN-based devices have high electron mobility and electron saturation velocity compared to silicon-based devices, which are currently commonly available, and thus can exhibit high frequency characteristics. In addition, the application of such high electron mobility to GaN-based devices allows for improved on-resistance characteristics, thereby enabling the implementation of low-loss switching devices.

As described above, GaN-based field effect transistors (FETs) are sufficiently advantageous as devices that require high-frequency and high-power characteristics, so ongoing research is in progress. While these GaN-based FETs have been widely studied and developed over the years, there are still several issues regarding device reliability that need to be addressed.

The breakdown voltage is the most important characteristic to secure, especially in nitride-based semiconductor devices capable of normally-off operation. To improve the breakdown voltage characteristics of devices, methods of forming a field plate on a gate electrode are currently utilized. However, additional processes, such as formation of mask patterns, deposition of insulation films and metal layers, and etching of insulation films and metal layers, are required to form field plates, which may reduce the overall process efficiency. In addition, when etching insulation films and metal layers through plasma dry etching, plasma damage occurs to substructures, which may undermine device reliability.

Furthermore, one of the important issues with nitride-based semiconductors is the current collapse caused by traps in semiconductors.

To solve the above-described problem, the inventors of the present disclosure have proposed a novel group III-V power semiconductor device and a method of manufacturing the same, the contents of which will be described in detail later.

### DOCUMENT OF RELATED ART

### Patent Document

Korean Patent Application Publication No. 10-2020-0068745 “High-Electron-Mobility Transistor”

### SUMMARY

The present disclosure, which has been devised to address the above-described issues in the related art, aims to provide a group III-V power semiconductor device in which one or more electric field relaxation regions are formed on a barrier layer, preferably between a capping layer and a drain electrode, thereby relaxing the peak electric field between a gate electrode and the drain electrode so that the characteristics of the device are improved, and a method of manufacturing the same.

In addition, the present disclosure aims to provide a group III-V power semiconductor device in which an electric field relaxation region is formed in a capping layer, on an edge side of the capping layer facing a drain electrode, so that an electric field concentrated on an edge side of a gate electrode is easily relaxed, and a method of manufacturing the same.

In addition, the present disclosure aims to provide a group III-V power semiconductor device in which one or more electric field relaxation regions that are spaced from a capping layer are formed so that an electric field concentrated on an edge side of a gate electrode or the capping layer is easily relaxed, and a method of manufacturing the same.

In addition, the present disclosure aims to provide a group III-V power semiconductor device in which a first region and a second region are formed within a single electric field relaxation region under different ion implantation conditions so that an electric field concentrated on an edge side of a gate electrode is easily relaxed, and a method of manufacturing the same.

In addition, the present disclosure aims to provide a group III-V power semiconductor device in which only an ion implantation process is added when forming an electric field relaxation region, thereby preventing the process efficiency from being reduced as much as possible, and a method of manufacturing the same.

In addition, the present disclosure aims to provide a group III-V power semiconductor device in which a hole injection region is formed to capture electrons trapped on a side adjacent to a barrier layer, thereby preventing current collapse and degradation of the on-resistance characteristics of the device, and a method of manufacturing the same.

The present disclosure may be implemented by embodiments having the following configurations to achieve the above-described objectives.

In one embodiment of the present disclosure, a group III-V power semiconductor device, according to the present disclosure, is characterized by including: a substrate; a channel layer on the substrate; a barrier layer on the channel layer; a capping layer on the barrier layer; a gate electrode on the capping layer; a source electrode and a drain electrode that are disposed while being spaced from each other with the gate electrode disposed therebetween; and an electric field relaxation region in the capping layer.

In another embodiment of the present disclosure, the group III-V power semiconductor device, according to the present disclosure, is characterized in that the electric field relaxation region has a narrower width size along a first direction than the capping layer.

In a further embodiment of the present disclosure, the group III-V power semiconductor device, according to the present disclosure, is characterized in that the electric field relaxation region is disposed at an edge part of the capping layer, the edge part facing the drain electrode along the first direction.

In a further embodiment of the present disclosure, the group III-V power semiconductor device, according to the present disclosure, is characterized in that the electric field relaxation region is an ion implantation region in the capping layer.

In a further embodiment of the present disclosure, the group III-V power semiconductor device, according to the present disclosure, is characterized in that the electric field relaxation region is a region where one or more elements of Ar, N, O, Si, and H are implanted through ion implantation.

In a further embodiment of the present disclosure, the group III-V power semiconductor device, according to the present disclosure, is characterized in that the electric field relaxation region has a lower hole concentration than the capping layer.

In a further embodiment of the present disclosure, the group III-V power semiconductor device, according to the present disclosure, is characterized by further including: an insulation film covering the gate electrode; and a field plate on the insulation film, wherein the field plate covers an edge part of the gate electrode, the edge part facing the drain electrode along a first direction.

In a further embodiment of the present disclosure, the group III-V power semiconductor device, according to the present disclosure, is characterized by further including: a hole injection region on the barrier layer, between the electric field relaxation region and the drain electrode; and a connection layer that is disposed on the hole injection region and is electrically connected with the drain electrode.

In a further embodiment of the present disclosure, the group III-V power semiconductor device, according to the present disclosure, is characterized in that the hole injection region has a lower hole concentration than the electric field relaxation region.

In a further embodiment of the present disclosure, a group III-V power semiconductor device, according to the present disclosure, is characterized by including: a substrate; a channel layer on the substrate; a barrier layer on the channel layer, the barrier layer including a material that differs from that of the channel layer; a capping layer on the barrier layer; a gate electrode on the capping layer; a source electrode and a drain electrode that are disposed while being spaced from each other with the gate electrode disposed therebetween; and a first electric field relaxation region between the capping layer and the drain electrode, the first electric field relaxation region being spaced from the capping layer and the drain electrode along a first direction.

In a further embodiment of the present disclosure, the group III-V power semiconductor device, according to the present disclosure, is characterized in that the first electric field relaxation region has a lower resistance than the capping layer.

In a further embodiment of the present disclosure, the group III-V power semiconductor device, according to the present disclosure, is characterized in that the first electric field relaxation region is an ion implantation region in a p-GaN layer.

In a further embodiment of the present disclosure, the group III-V power semiconductor device, according to the present disclosure, is characterized in that the first electric field relaxation region includes: a first region on a side adjacent to the capping layer along the first direction; and a second region on a side distant from the capping layer along the first direction, and the first and second regions differ from each other in resistance values.

In a further embodiment of the present disclosure, the group III-V power semiconductor device, according to the present disclosure, is characterized in that the first region has a lower resistance than the second region.

In a further embodiment of the present disclosure, the group III-V power semiconductor device, according to the present disclosure, is characterized by further including: a second electric field relaxation region in the capping layer.

In a further embodiment of the present disclosure, the group III-V power semiconductor device, according to the present disclosure, is characterized in that the second electric field relaxation region is disposed at an edge part of the capping layer, the edge part facing the drain electrode along the first direction.

In one embodiment of the present disclosure, a method of manufacturing a group III-V power semiconductor device, according to the present disclosure, is characterized by including the following steps: sequentially forming a buffer layer, a channel layer, and a barrier layer on a substrate; forming a capping layer doped with a first conductivity type on the barrier layer; forming a first electric field relaxation region in the capping layer; forming a source electrode and a drain electrode that are spaced from each other on the barrier layer; and forming a gate electrode on the capping layer, wherein the first electric field relaxation region has a narrower width along a first direction than the capping layer.

In another embodiment of the present disclosure, the method of manufacturing the group III-V power semiconductor device, according to the present disclosure, is characterized in that the first electric field relaxation region is formed through ion implantation of one or more elements of Ar, N, O, Si, and H into the capping layer.

In a further embodiment of the present disclosure, the method of manufacturing the group III-V power semiconductor device, according to the present disclosure, is characterized by further including a step of forming a second electric field relaxation region on the barrier layer, between the capping layer and the drain electrode.

In a further embodiment of the present disclosure, the method of manufacturing the group III-V power semiconductor device, according to the present disclosure, is characterized in that the step of forming the second electric field relaxation region includes the following steps: forming a doped layer on the barrier layer by growing a GaN layer with the first conductivity type; forming the capping layer and a doped region between the capping layer and the drain electrode by etching the doped layer; and performing an ion implantation process in the doped region.

The present disclosure has the following effects based on the above-described configurations.

The present disclosure has an effect of forming one or more electric field relaxation regions on a barrier layer, preferably between a capping layer and a drain electrode, thereby relaxing the peak electric field between a gate electrode and the drain electrode so that the characteristics of the device are improved.

In addition, the present disclosure has an effect of forming an electric field relation region in a capping layer, on an edge side of the capping layer facing a drain electrode, so that an electric field concentrated on an edge side of a gate electrode is easily relaxed.

In addition, the present disclosure derives an effect of forming one or more electric field relaxation regions that are spaced from a capping layer so that an electric field concentrated on an edge side of a gate electrode or the capping layer is easily relaxed.

In addition, the present disclosure derives an effect of forming a first region and a second region within a single electric field relaxation region under different ion implantation conditions so that an electric field concentrated on an edge side of a gate electrode is easily relaxed.

In addition, the present disclosure shows an effect of adding only an ion implantation process when forming an electric field relaxation region, thereby preventing the process efficiency from being reduced as much as possible.

In addition, the present disclosure has an effect of forming a hole injection region to capture electrons trapped on a side adjacent to a barrier layer, thereby preventing current collapse and degradation of the on-resistance characteristics of the device.

In the meantime, it is further stated that even when not explicitly mentioned herein, the effects hereinafter expected by the technical features of the present disclosure and potential effects thereof are treated as those described herein of the present disclosure.

### BRIEF DESCRIPTION OF THE DRAWINGS

FIG. 1 is a plan view illustrating a group III-V power semiconductor device according to a first embodiment of the present disclosure;

FIG. 2 is a cross-sectional view along the line AA′ illustrating the group III-V power semiconductor device based on FIG. 1;

FIG. 3 is a plan view illustrating a group III-V power semiconductor device according to a second embodiment of the present disclosure;

FIGS. 4 and 5 are cross-sectional views along the line BB′ illustrating the group III-V power semiconductor device based on FIG. 3;

FIG. 6 is a plan view illustrating a group III-V power semiconductor device according to a third embodiment of the present disclosure;

FIG. 7 is a cross-sectional view along the line CC′ illustrating the group III-V power semiconductor device based on FIG. 6; and

FIGS. 8 to 15 are cross-sectional views illustrating a method of manufacturing a group III-V power semiconductor device according to one embodiment of the present disclosure.

### DETAILED DESCRIPTION

Hereinafter, embodiments of the present disclosure will be described in more detail with reference to the attached drawings. The embodiments of the present disclosure may be modified in various forms, and the scope of the present disclosure should not be construed as being limited to the following embodiments but should be construed on the basis of the appended claims. In addition, these embodiments are only provided for reference to more completely describe the present disclosure to those of ordinary skill in the art to which the present disclosure pertains.

Hereinafter, it should be noted that when one component (or layer) is described as being disposed on another component (or layer), one component may be disposed directly on another component, or another component(s) or layer(s) may be disposed between the components. In addition, when one component is expressed as being directly disposed on or above another component, no other component(s) are disposed between the components. Furthermore, being disposed “on”, “on an upper portion of”, “on a lower portion of”, “above”, “below”, “on one (first) side of”, or “on one side surface of” a component implies a relative positional relationship.

In addition, terms such as first, second, and the like may be used to describe various items, such as various elements, regions, and/or portions, but these items are not limited by such terms.

It should also be noted that when certain embodiments are implementable otherwise, certain processes may be performed in an order that differs from that described below. For example, two processes described sequentially may be substantially performed simultaneously or inversely.

Furthermore, a conductivity type or a doped region of components may be defined as “p-type” or “n-type” depending on the characteristics of main carriers, but this is only for the benefit of description, and the technical idea of the present disclosure is not limited as exemplified. For example, the more general term “first conductivity type” or “second conductivity type” will be used hereinafter for the “p-type” or “n-type”. In this case, the first conductivity type refers to the p-type, and the second conductivity type refers to the n-type.

It should also be understood that the terms “high concentration” and “low concentration” that express doping concentrations of impurity regions may refer to relative doping concentrations of one component and other components.

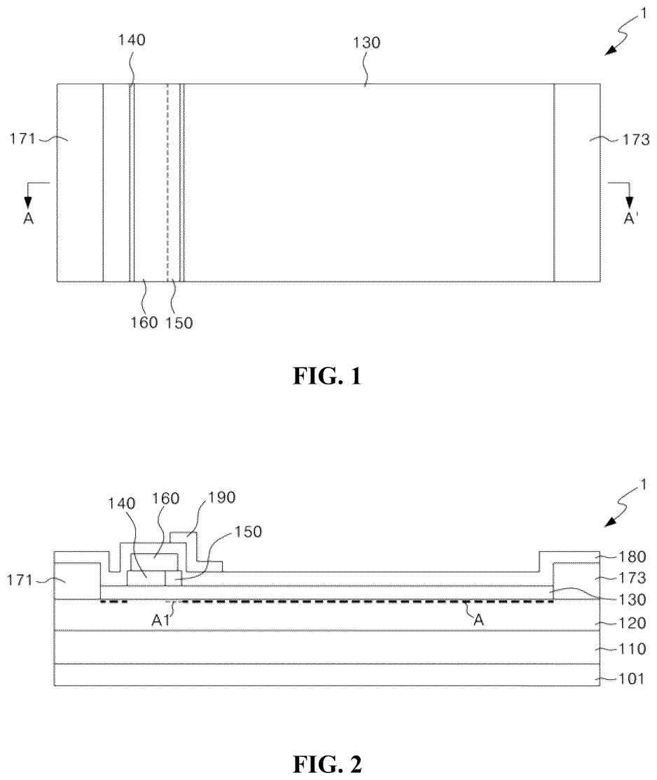

In addition, in the plan view illustrated in FIG. 1, an x-axis direction (the direction in which a gate electrode and a drain electrode are spaced apart) is set as a “first direction”, while a y-axis direction (the direction orthogonal to the x-axis direction on the same horizontal plane) is set as a “second direction”.

FIG. 1 is a plan view illustrating a group III-V power semiconductor device according to a first embodiment of the present disclosure, and FIG. 2 is a cross-sectional view along the line AA′ illustrating the group III-V power semiconductor device based on FIG. 1. It should be noted that in the plan view illustrated in FIG. 1, an insulation film and a field plate are omitted for the benefit of description.

Hereinafter, a group III-V power semiconductor device 1, according to the first embodiment of the present disclosure, will be described in detail with reference to the attached drawings. In addition, the “group III-V power semiconductor device 1” hereinafter may be, for example, a nitride-based power semiconductor device.

Referring to FIGS. 1 and 2, the present disclosure relates to the group III-V power semiconductor device 1. More particularly, the present disclosure relates to the group III-V power semiconductor device 1 in which one or more electric field relaxation regions 150 are formed on a barrier layer 130, preferably between a capping layer 140 and a drain electrode 173, thereby relaxing the peak electric field between a gate electrode 160 and the drain electrode 173 so that the characteristics of the device are improved.

First, the group III-V power semiconductor device 1, according to the first embodiment of the present disclosure, may include a substrate 101. The substrate 101, which is a substrate for growth, may, for example, be a silicon substrate, but there are no limitations. Other examples thereof may include a sapphire substrate, a GaN substrate, or a SiC substrate. In the present disclosure, an example where the substrate 101 is a silicon substrate is to be described.

In addition, a buffer layer 110 may be formed on the substrate 101. The buffer layer 110 may be formed, for example, by growing AlN on the substrate 101 to a predetermined thickness. Alternatively, the buffer layer 110 may have a form in which a single layer of GaN or AlGaN or a composite layer of one or more of the foregoing GaN and AlGaN is grown, but there are no limitations. Such a buffer layer 110 may be a structure configured to prevent stress caused by differences in lattice constants and thermal expansion coefficients between the substrate 101 and a channel layer 120 to be described later. The buffer layer 110 may also be doped with impurities such as C and/or Fe. However, it should be noted that the buffer layer 110 is not an essential component of the present disclosure.

The channel layer 120 is formed to have a predetermined thickness on the substrate 101, more preferably on the buffer layer 110, and may, for example, be made of a semiconductor layer based on a nitride such as GaN. In addition, a barrier layer 130 is formed to have a predetermined thickness on the channel layer 120 and may, for example, be a semiconductor layer based on a nitride such as AlGaN. However, the scope of the present disclosure is not limited thereto. Such channel layer 120 and barrier layer 130 are preferably formed of nitride-based semiconductor layers that differ from each other. On the basis of such a structure, a two-dimensional electron gas (2DEG) layer A may be formed near the interface between the channel layer 120 and the barrier layer 130. In this case, the density and mobility of the 2DEG layer A may be controlled by adjusting the Al and Ga contents in the barrier layer 130. In addition, the 2DEG layer A may be formed in the channel layer 120.

In addition, the capping layer 140 may be formed on the barrier layer 130. The capping layer 140 is configured to be formed between the barrier layer 130 and the gate electrode 160. The capping layer 140 may cause depletion of the 2DEG layer A immediately below the gate electrode 160 and preferably has a positive polarity. When such a capping layer 140 is formed to a predetermined or larger thickness, the gate electrode 160 and the 2DEG layer A become more distant, resulting in a longer response time. In contrast, when formed to a predetermined or smaller thickness, it is difficult to achieve the normally-off operation. Therefore, the thickness thereof is preferably formed at a suitable level, which is, for example, in the range of 10 nm to 1000 nm, but there are no limitations.

In addition, the capping layer 140 may be formed by growing p-GaN and may, for example, be formed by doping GaN with Mg. The capping layer 140 may also include a material formed by a difference in composition ratio based on a combination of x and y in an AlₓIn_{y}Ga_{1-x-y}N material (x+y<1).

In addition, the electric field relaxation region 150 may be formed on the barrier layer 130. Such an electric field relaxation region 150 may be formed in the capping layer 140. In this case, the electric field relaxation region 150 preferably has a narrower width size along the first direction than the capping layer 140. Accordingly, the capping layer 140 may function properly to enable the normally-off operation of the device 1. Furthermore, the electric field relaxation region 150 preferably has a thickness along the vertical direction that is the same as or smaller than that of the capping layer 140 and more preferably has a thickness that is substantially the same as that of the capping layer 140. However, the scope of the present disclosure is not limited thereto.

Such an electric field relaxation region 150 may be formed in the capping layer 140, in any location along the first direction. In one example, the electric field relaxation region 150 may be formed around the center of the capping layer 140 along the first direction. In another example, the electric field relaxation region 150 may be formed in the capping layer 140, on a side adjacent to that facing the drain electrode 173 along the first direction. Typically, when the group III-V power semiconductor device 1 operates, an electric field is concentrated at an edge part of the gate electrode 160, the edge part on a side adjacent to the drain electrode 173. Thus, to relax the concentrated electric field, the electric field relaxation region 150 is preferably formed around an edge part of the capping layer 140, the edge part on a side facing the drain electrode 173 in the capping layer 140.

By forming the electric field relaxation region 150 as described above, the peak electric field between the gate electrode 160 and the drain electrode 173 can be relaxed. Accordingly, the electric field relaxation region 150 can perform the function of field plates. The following processes are necessary to form field plates: deposition of an insulation film, etching, deposition of a conductive film, and etching. However, the electric field relaxation region 150 can be formed relatively simply compared to field plates. In addition, implantation conditions such as implantation elements, ion implantation concentration, and ion implantation energy in the electric field relaxation region 150 may be varied to provide further flexible control over desired characteristics compared to field plates.

Furthermore, the electric field relaxation region 150 may be formed through ion implantation of one or more elements of Ar, N, O, Si, and H into the capping layer 140. In one example, the ion implantation of H element into the capping layer 140 may passivate the capping layer 140 made of Mg-doped GaN. Accordingly, the capping layer 140 may lose the unique function thereof. As a result, the hole concentration of the capping layer 140 is reduced, and a 2DEG layer A1 immediately below the electric field relaxation region 150 is activated, in which case the 2DEG layer A1 preferably has a relatively lower concentration than the 2DEG layer A.

In another example, the ion implantation of elements such as Ar and/or N into the capping layer 140 may cause lattice damage in the capping layer 140 based on p-GaN, thereby reducing the polarization charge of the capping layer 140. On this basis, the 2DEG layer A1 having a relatively low concentration may be formed below the electric field relaxation region 150. In addition, the ion implantation of H element into the capping layer 140 at high energy and/or high concentration may cause lattice damage in the capping layer 140.

For the following description, the gate electrode 160 may be formed on the capping layer 140. The gate electrode 160 may, for example, be formed of a single layer or composite layer made of various metals, such as Ti and Pd. The depletion layer of such a gate electrode 160 may penetrate the barrier layer 130, reaching the channel layer 120 and thus blocking the 2DEG layer A.

In addition, a source electrode 171 and the drain electrode 173 may be formed on the barrier layer 130 while being spaced from each other. In some cases, the source electrode 171 and the drain electrode 173 may be formed such that the lower portions thereof are disposed in the barrier layer 130, on the interface between the barrier layer 130 and the channel layer 120, in the channel layer 120, or on the barrier layer 130. However, there are no particular limitations.

The source electrode 171 and the drain electrode 173 may be disposed in an active region while being spaced from each other along the first direction, with the gate electrode 160 disposed therebetween. Such source electrode 171 and drain electrode 173, which are ohmic contact regions, may, for example, have a square cross-sectional shape or a stepped cross-sectional shape. However, the scope of the present disclosure is not limited by any particular examples. In addition, the source electrode 171 and the drain electrode 173 may, for example, include a single layer or composite layer made of various metals capable of ohmic contact, such as Ti, Au, and Al. However, there are no particular limitations.

In addition, an insulation film 180 may be formed on the barrier layer 130. Additionally, the insulation film 180 may be formed on the barrier layer 130 so that the gate electrode 160, the source electrode 171, and the drain electrode 173 are covered. Such an insulation film 180 may be made of an electrically insulating material, for example, Al₂O₃, but there are no particular limitations, and may also include any oxide film, nitride film, or the like. Although the insulation film 180 in FIG. 2 is illustrated as covering the source electrode 171 and the drain electrode 173, at least one side of the source electrode 171 and the drain electrode 173 may be exposed in the following process.

In addition, a field plate 190 may further be formed on the insulation film 180. Such a field plate 190 is preferably formed on a side adjacent to the gate electrode 160 and is more preferably formed between the gate electrode 160 and the drain electrode 173. The field plate 190 is configured to relax the peak electric field between the gate electrode 160 and the drain electrode 173. Between the gate electrode 160 and the drain electrode 173, the electric field may be concentrated at the edge part of the gate electrode 160, as described above. Thus, the field plate 190 is preferably formed on the edge part of the gate electrode 160, the edge part on a side facing the drain electrode 173. In addition, the field plate 190 may be electrically connected with the source electrode 171. However, one embodiment of the present disclosure provides a separate electric field relaxation region 150, so it should be noted that the field plate 190 is not an essential component of the present disclosure.

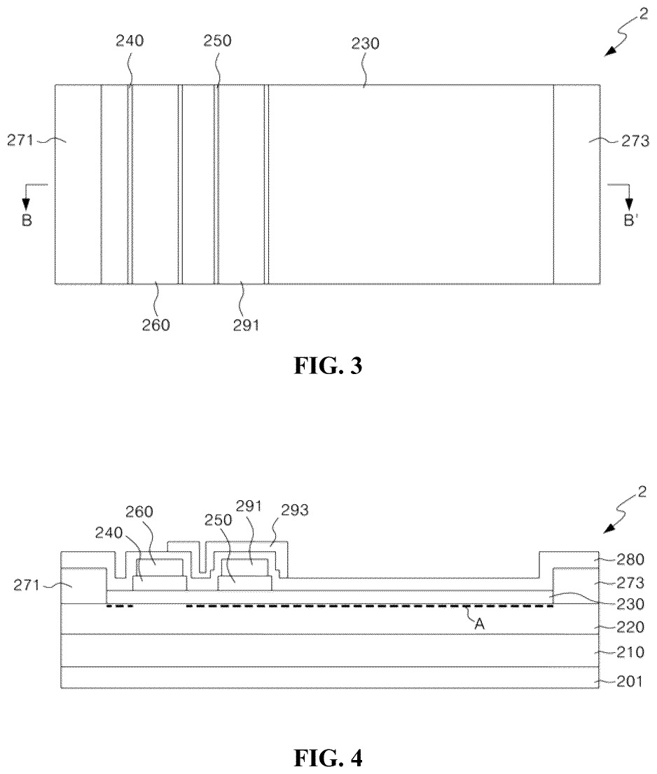

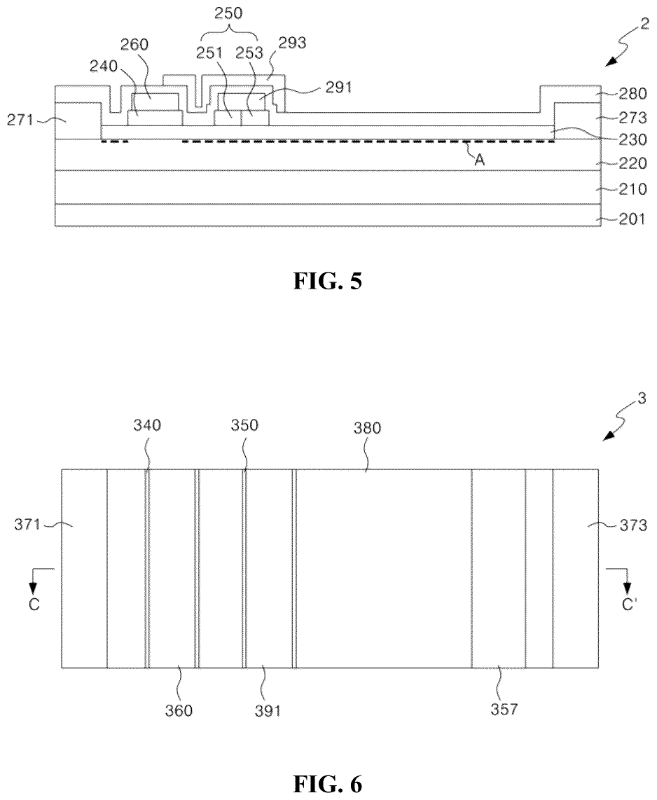

FIG. 3 is a plan view illustrating a group III-V power semiconductor device according to a second embodiment of the present disclosure, and FIGS. 4 and 5 are cross-sectional views along the line BB′ illustrating the group III-V power semiconductor device based on FIG. 3. In the plan view illustrated in FIG. 3, an insulation film and a second field plate are omitted for the benefit of description.

Hereinafter, a group III-V power semiconductor device 2, according to the second embodiment of the present disclosure, will be described in detail with reference to the attached drawings. In the illustrated drawings, components that are substantially identical to those in the first embodiment are designated by changing the first digit of the reference numeral in the drawings from “1” to “2”, and for convenience, descriptions of duplicated components are to be omitted. In addition, an electric field relaxation region 250, according to the second embodiment, may be combined with the semiconductor device 1, according to the first embodiment.

Referring to FIGS. 3 and 4, the group III-V power semiconductor device 2, according to the second embodiment, may have the electric field relaxation region 250 that is spaced from a capping layer 240, on a barrier layer 230. In this case, the electric field relaxation region 250 may be formed on the barrier layer 230, between the capping layer 240 and a drain electrode 273. As will be described below, such an electric field relaxation region 250 may be formed by forming a p-GaN layer for forming the capping layer 240, then etching the p-GaN layer, and performing an ion implantation process. In other words, only the ion implantation process is added to form the electric field relaxation region 250.

In addition, the electric field relaxation region 250 may be formed by performing the ion implantation process, which is covered by the description for the electric field relaxation region 150 according to the first embodiment. Furthermore, a plurality of electric field relaxation regions 250 that are spaced apart from each other along the first direction may be formed between the capping layer 240 and the drain electrode 273 while being spaced from the capping layer 240 and the drain electrode 273. Alternatively, a single region may be formed, as illustrated in the drawings.

In addition, the single electric field relaxation region 250 may have a first region 251 and a second region 253, along the first direction (see FIG. 5). The first region 251 is relatively adjacent to the capping layer 240 along the first direction, while the second region 253 is relatively adjacent to the drain electrode 273. The first region 251 and the second region 253 may be formed within the single electric field relaxation region 250 under different ion implantation conditions. The term “different ion implantation conditions” above is understood to refer to the case where one or more conditions of ion implantation elements, ion implantation energy, and ion implantation concentration differ from each other.

In this case, the first region 251, which has a higher ion implantation concentration and/or ion implantation energy than the second region 253, may be a low-resistance region, while the second region 253 may be a high-resistance region. Therefore, the electric field concentration on the edge side of the gate electrode 260 may be mitigated by the first region 251, and three or more ion implantation regions may be formed within the electric field relaxation region 250 in some cases. Furthermore, the first region 251 and the second region 253 may be in contact with or spaced from each other.

The electric field relaxation region 250, according to the second embodiment, is configured to mitigate the electric field concentration on the edge side of the gate electrode 260 and is formed to be spaced from the capping layer 240. Thus, to prevent the concentration of a 2DEG layer A from being reduced, a higher ion implantation element concentration or a relatively higher ion implantation energy is preferable during the ion implantation process, compared to that of the electric field relaxation region 150 according to the first embodiment. However, the scope of the present disclosure is not limited thereto.

In addition, a first field plate 291 may be formed on the top surface of the electric field relaxation region 250. In one example, the bottom surface of the first field plate 291 may be in contact with the top surface of the electric field relaxation region 250. Furthermore, a second field plate 293 may be formed on an insulation film 280 on the gate electrode 260 and the first field plate 291. In this case, both the first field plate 291 and the second field plate 293 may be electrically connected with a source electrode 271. Alternatively, the second field plate 293 may be formed to traverse the electric relaxation region 250 along the first direction from an upper edge part of the gate electrode 260, the upper edge part on a side facing the drain electrode 273. In this case, the second field plate 293 may have a stepped cross-sectional shape.

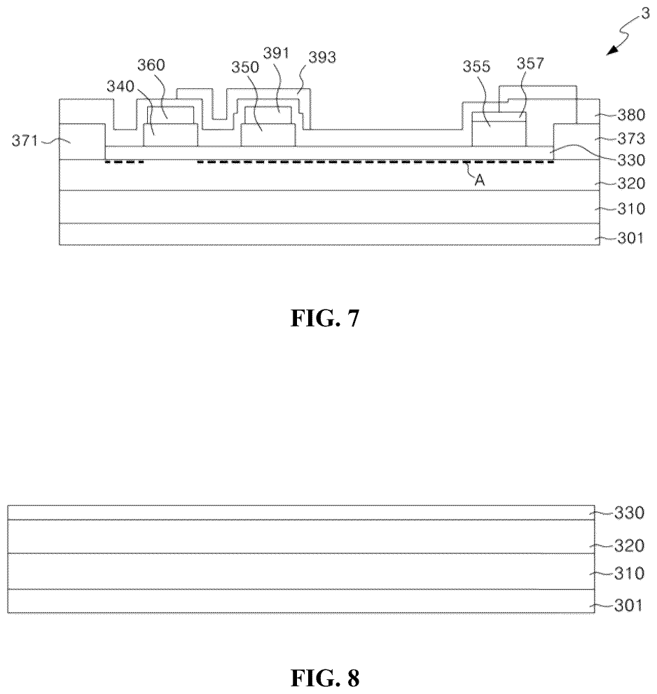

FIG. 6 is a plan view illustrating a group III-V power semiconductor device according to a third embodiment of the present disclosure, and FIG. 7 is a cross-sectional view along the line CC′ illustrating the group III-V power semiconductor device based on FIG. 6. In the plan view illustrated in FIG. 6, an insulation film and a second field plate are omitted for the benefit of description.

Hereinafter, a group III-V power semiconductor device 3, according to the third embodiment of the present disclosure, will be described in detail with reference to the attached drawings. In the illustrated drawings, components that are identical to those in the first embodiment are designated by changing the first digit of the reference numeral in the drawings from “1” to “3”, and for convenience, descriptions of duplicated components are to be omitted.

In addition, a hole injection region 355, according to the third embodiment, may be combined with the semiconductor device 1, according to the first embodiment, or with the semiconductor device 2, according to the second embodiment.

Referring to FIGS. 6 and 7, the group III-V power semiconductor device 3, according to the third embodiment, may further include the hole injection region 355. For example, the hole injection region 355 is configured to be formed on a barrier layer 330, between an electric field relaxation region 350 and a drain electrode 373. Such a hole injection region 355 is where holes are injected to capture electrons trapped on a side adjacent to the barrier layer 330. In other words, holes are injected into a 2DEG layer A, thereby allowing such holes to bind to trapped electrons so that the electrical resistance of the device 3 can be reduced, and the memory effect can thus be minimized. Such a hole injection region 355 may be formed in the same manner as the electric field relaxation region 250, according to the second embodiment, so the detailed descriptions thereof are to be omitted. Furthermore, the hole injection region 355, according to the third embodiment, is preferably formed such that the impact on the concentration of the 2DEG layer A therebelow is minimized properly.

In addition, a connection layer 357 may be formed on the hole injection region 355. The connection layer 357, which is in contact with the hole injection region 355, may be electrically connected with the drain electrode 373. Such a connection layer 357 is preferably formed substantially at the same time during the process of forming the drain electrode 373. Thus, the connection layer 357 and the drain electrode 373 may include the same material.

FIGS. 8 to 15 are cross-sectional views illustrating a method of manufacturing a group III-V power semiconductor device according to one embodiment of the present disclosure.

Hereinafter, a method of manufacturing the group III-V power semiconductor device 3, according to the third embodiment of the present disclosure, will be described in detail with reference to the attached drawings.

Referring to FIG. 8, a buffer layer 310, a channel layer 320, and a barrier layer 330 may be first formed sequentially on a substrate 301. The substrate 301, which is a substrate for growth as described above, may be any one of a silicon substrate, a sapphire substrate, a GaN substrate, and a SiC substrate, but the description in the present disclosure is based on one example being a silicon substrate. The buffer layer 310 may be formed on the substrate 301 and under the channel layer 320, for example, by growing an AlN layer to a predetermined thickness. In addition, the channel layer 320 to be formed on the buffer layer 310 is a semiconductor layer based on a nitride such as GaN, and the barrier layer 330 is a semiconductor layer based on a nitride such as AlGaN. By electrons accumulated at the interface between the channel layer 320 and the barrier layer 330, a 2DEG layer A may be formed.

For a detailed description, piezoelectric polarization may occur at the interface between the channel layer 320 and the barrier layer 330, for example, due to differences in lattice constants between GaN and AlGaN. In this case, the piezoelectric polarization effect and the spontaneous polarization effect of the channel layer 320 and the barrier layer 330 may function, thereby generating two-dimensional electron gas with a high electron concentration at the interface between the two configurations.

Then, a capping layer 340, an electric field relaxation region 350, and a hole injection region 355 may be formed on the barrier layer 330. The capping layer 340, the electric field relaxation region 350, and the hole injection region 355 may be sequentially formed while being spaced from each other along the first direction. Hereinafter, the processes of forming the capping layer 340, the electric field relaxation region 350, and the hole injection region 355 are to be described in detail.

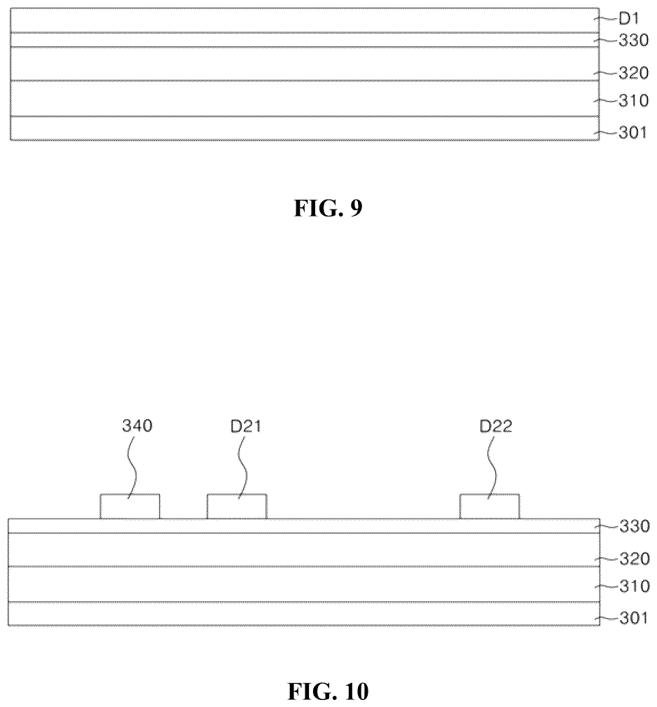

Referring to FIG. 9, a doped layer D1 may be formed first on the barrier layer 330, for example, by growing a GaN layer with the first conductivity type. Referring to FIG. 10, the doped layer D1 may then be etched utilizing a mask pattern (not shown) to form the capping layer 340 and a plurality of doped regions that are spaced from each other along the first direction. For the benefit of description, the doped region relatively adjacent to the capping layer 340 is referred to as a “first doped region D21”, while the doped region relatively distant from the capping layer 340 is referred to as a “second doped region D22”.

The electric field relaxation region 350 and the hole injection region 355 are sequentially formed thereafter. In this case, the electric field relaxation region 350 may be formed first, or the hole injection region 355 may be formed first, meaning that there are no limitations in the formation order. Hereinafter, the description is based on the case where the electric field relaxation region 350 is formed first.

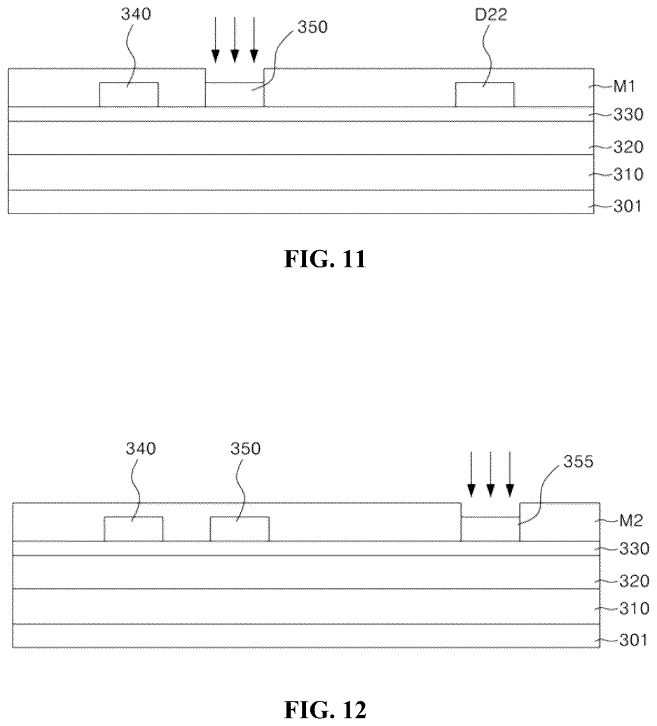

Referring to FIG. 11, a first mask pattern M1 is formed first on the barrier layer 330. The first mask pattern M1 may be formed such that at least one side of the top surface of the first doped region D21 is exposed while the capping layer 340 and the second doped region D22 are covered. Then, the electric field relaxation region 350 may be completed by performing an ion implantation process on the first doped region D21. Subsequently, the first mask pattern M1 is removed. In this process, when the ion implantation process is performed in the capping layer 140 utilizing the first mask pattern M1, the electric field relaxation region 350, according to the third embodiment, may be completed.

Referring to FIG. 12, a second mask pattern M2 is then formed on the barrier layer 330. The second mask pattern M2 may be formed such that at least one side of the top surface of the second doped region D22 is exposed while the capping layer 340 and the electric field relaxation region 350 are covered. Then, the hole injection region 355 may be completed by performing an ion implantation process on the second doped region D22. Subsequently, the second mask pattern M2 is removed. The ion implantation processes for completing the electric field relaxation region 350 and the hole implantation region 355 are covered by the description above.

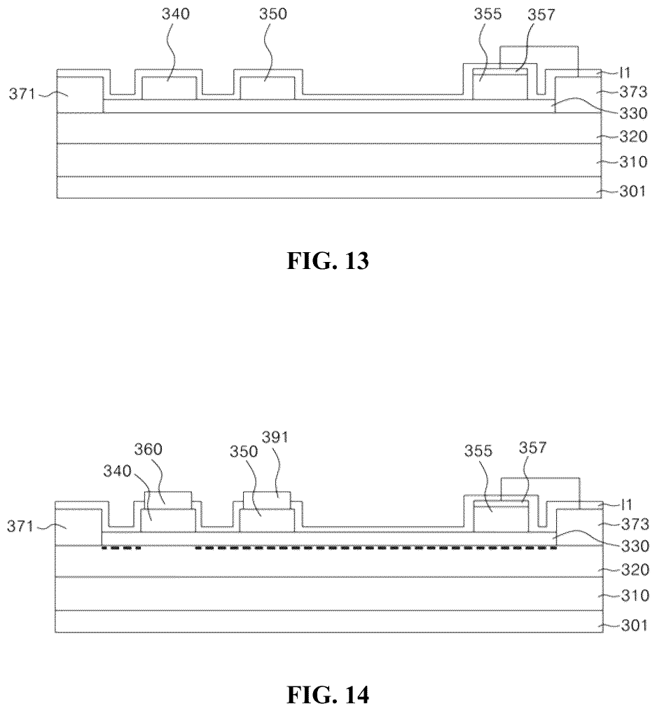

Referring to FIG. 13, a source electrode 371 and a drain electrode 373 may then be formed at given locations. The source electrode 371 and the drain electrode 373 may be formed by depositing a metal layer (not shown) and performing an etching process. In this process, a connection layer 357 is also preferably formed in conjunction. Then, a first insulation layer I1 may be deposited on the barrier layer 330.

Referring to FIG. 14, a gate electrode 360 may be formed by etching the first insulation layer I1, depositing a gate film (not shown), and performing an etching process. In this case, a first field plate 391 may be formed in conjunction.

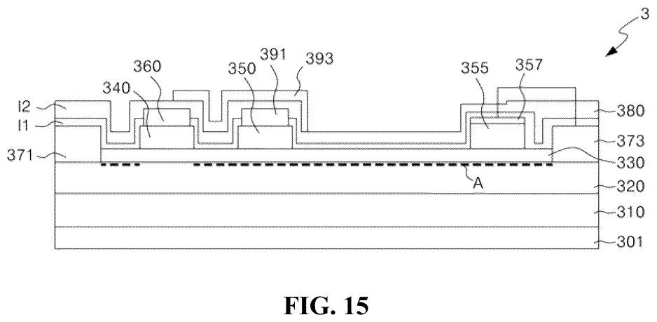

Referring to FIG. 15, a second insulation layer I2 may then be deposited on the first insulation layer I1 to form a second field plate 393. On the basis of the first insulation layer I1 and the second insulation layer I2, an insulation film 380 may be completed.

The detailed description above is illustrative of the present disclosure. In addition, the description above shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or the scope of skill or knowledge in the art to which the present disclosure pertains. The above-described embodiments describe the best state for implementing the technical idea of the present disclosure, and various changes required in the specific application field and use of the present disclosure are possible. Therefore, the detailed description of the present disclosure above is not intended to limit the present disclosure to the embodiments disclosed herein.

What is claimed is:

1. A group III-V power semiconductor device comprising:
a substrate;
a channel layer disposed on the substrate;
a barrier layer disposed on the channel layer;
a capping layer disposed on the barrier layer;
a gate electrode disposed on the capping layer;
a source electrode and a drain electrode that are disposed while being spaced from each other with the gate electrode being disposed therebetween; and
an electric field relaxation region disposed in the capping layer.

2. The group III-V power semiconductor device of claim 1, wherein the electric field relaxation region has a width size narrower than a width size of the capping layer along a first direction.

3. The group III-V power semiconductor device of claim 2, wherein the electric field relaxation region is disposed at an edge part of the capping layer, the edge part facing the drain electrode along the first direction.

4. The group III-V power semiconductor device of claim 1, wherein the electric field relaxation region is an ion implantation region in the capping layer.

5. The group III-V power semiconductor device of claim 4, wherein the electric field relaxation region is a region where one or more elements of Ar, N, O, Si, and H are implanted through ion implantation.

6. The group III-V power semiconductor device of claim 1, wherein the electric field relaxation region has a hole concentration lower than a hole concentration of the capping layer.

7. The group III-V power semiconductor device of claim 1, further comprising:
an insulation film covering the gate electrode; and
a field plate disposed on the insulation film,
wherein the field plate covers an edge part of the gate electrode, the edge part facing the drain electrode along a first direction.

8. The group III-V power semiconductor device of claim 1, further comprising:
a hole injection region disposed on the barrier layer, between the electric field relaxation region and the drain electrode; and
a connection layer that is disposed on the hole injection region and is electrically connected with the drain electrode.

9. The group III-V power semiconductor device of claim 8, wherein the hole injection region has a hole concentration lower than a hole concentration of the electric field relaxation region.

10. A group III-V power semiconductor device comprising:
a substrate;
a channel layer disposed on the substrate;
a barrier layer disposed on the channel layer, the barrier layer comprising a material that differs from a material of the channel layer;
a capping layer disposed on the barrier layer;
a gate electrode disposed on the capping layer;
a source electrode and a drain electrode that are disposed while being spaced from each other with the gate electrode being disposed therebetween; and
a first electric field relaxation region disposed between the capping layer and the drain electrode, the first electric field relaxation region being spaced from the capping layer and the drain electrode along a first direction.

11. The group III-V power semiconductor device of claim 10, wherein the first electric field relaxation region has a resistance lower than a resistance of the capping layer.

12. The group III-V power semiconductor device of claim 11, wherein the first electric field relaxation region is an ion implantation region in a p-GaN layer.

13. The group III-V power semiconductor device of claim 10,
wherein the first electric field relaxation region comprises:
a first region disposed on a side adjacent to the capping layer along the first direction; and
a second region disposed on a side more distant from the capping layer along the first direction than the first region, and
wherein the first region has a resistance value that differs from a resistance value of the second region.

14. The group III-V power semiconductor device of claim 13, wherein the first region has a resistance lower than a resistance of the second region.

15. The group III-V power semiconductor device of claim 10, further comprising:
a second electric field relaxation region disposed in the capping layer.

16. The group III-V power semiconductor device of claim 15, wherein the second electric field relaxation region is disposed at an edge part of the capping layer, the edge part facing the drain electrode along the first direction.

17. A method of manufacturing a group III-V power semiconductor device, the method comprising:
sequentially forming a buffer layer, a channel layer, and a barrier layer on a substrate;
forming a capping layer doped with a first conductivity type on the barrier layer;
forming a first electric field relaxation region in the capping layer;
forming a source electrode and a drain electrode that are spaced from each other on the barrier layer; and
forming a gate electrode on the capping layer,
wherein the first electric field relaxation region has a width narrower than a width of the capping layer along a first direction.

18. The method of claim 17, wherein the first electric field relaxation region is formed through ion implantation of one or more elements of Ar, N, O, Si, and H into the capping layer.

19. The method of claim 17, further comprising:
forming a second electric field relaxation region on the barrier layer, between the capping layer and the drain electrode.

20. The method of claim 19,
wherein the forming of the second electric field relaxation region comprises:
forming a doped layer on the barrier layer by growing a GaN layer with the first conductivity type;
forming, by etching the doped layer, the capping layer and a doped region, the doped region being formed between the capping layer and the drain electrode; and
performing an ion implantation process in the doped region.
